(19) United States
(12) Patent Application Publication
(10) Pub. No.: US 2012/0211272 A1
(43) Pub. Date: Aug. 23, 2012

(54) THIN FILM CIRCUIT BOARD DEVICE

(75) Inventor: Qing Zhang, Changshu (CN)

(73) Assignee: CHANGSHU SUNREX TECHNOLOGY CO., LTD., Changshu (CN)

(21) Appl. No.: 13/029,660

(22) Filed: Feb. 17, 2011

(51) Int. Cl. H05K 1/11

(52) U.S. Cl. 174/262

(57) ABSTRACT

A thin film circuit board device includes a multi-layered circuit unit having an upper circuit layer formed with an upper circuit having at least one first contact part, a lower circuit layer formed with a lower circuit having at least one second contact part disposed beneath the first contact part, and an insulating layer disposed between the upper and lower circuit layers and having at least one through hole. One of the upper and lower circuit layers has at least one preformed protruding portion that protrudes into the through hole toward the other one of the upper and lower circuit layers. One of the first and second contact parts is disposed on the preformed protruding portion so as to be in constant contact with the other one of the first and second contact parts.

### BACKGROUND OF THE INVENTION

1. Field of the Invention

The invention relates to a thin film circuit board device.

2. Description of the Related Art

A thin film circuit board device includes an upper thin film circuit layer, a lower thin film circuit layer, and an insulating layer disposed between the upper and lower thin film circuit layers. In order to electrically connect the upper and lower thin film circuit layers, the upper thin film circuit layer is formed with a first contact part, the lower thin film circuit layer is formed with a second contact part, the insulating layer has a through hole corresponding to the first and second contact parts, and a conductive adhesive is used to bond the first and second contact parts together in the through hole.

However, the adhesive property of the conductive adhesive may gradually become weaker after a long period of use such that the first and second contact parts are likely to separate from each other, thereby resulting in problems, for example, poor electrical connection.

In order to overcome the aforesaid drawbacks, another conventional thin film circuit board device is provided, which includes an upper thin film circuit layer formed with a plurality of first contact parts, a lower thin film circuit layer formed with a plurality of second contact parts disposed beneath the first contact parts, an insulating layer formed with a plurality of through holes, and a conductive adhesive bonding the first contact parts to the second contact parts. When separation occurs in one set of the first and second contact parts, electrical connection can still be established through the bonding among the remaining sets of the first and second contact parts. Nevertheless, as the service period of the conductive adhesive increases, it is still possible that all of the first and second contact parts would eventually separate from each other such that the aforesaid problem still occurs. Besides, the production cost may be increased due to provision of additional elements for connecting the upper and lower thin film circuit layers.

### SUMMARY OF THE INVENTION

The object of the present invention is to provide a thin film circuit board device that can enhance its function in terms of internal electrical connection and that can reduce production costs.

The thin film circuit board device according to the present invention comprises an upper circuit layer, a lower circuit layer, and an insulating layer. The upper circuit layer is formed with an upper circuit having at least one first contact part. The lower circuit layer is disposed below the upper circuit layer and is formed with a lower circuit having at least one second contact part disposed beneath the first contact part. The insulating layer is disposed between the upper and lower circuit layers and has at least one through hole corresponding to the first and second contact parts. One of the upper and lower circuit layers has at least one preformed protruding portion that protrudes into the through hole toward the other one of the upper and lower circuit layers. One of the first and second contact parts is disposed on the preformed protruding portion so as to be in constant contact with the other one of the first and second contact parts.

In an embodiment of this invention, the upper circuit layer has the preformed protruding portion, and the first contact part is formed on the preformed protruding portion, extends into the through hole and contacts the second contact part. Preferably, the lower circuit layer has a pressed portion having a concave face on which the second contact part is formed, and a convex face opposite to the concave face.

In another embodiment of this invention, the lower circuit layer has the preformed protruding portion, and the second contact part is formed on the preformed protruding portion, extends into the through hole and contacts the first contact part. Preferably, the upper circuit layer has a pressed portion having a concave face on which the first contact part is formed, and a convex face opposite to the concave face.

Preferably, the thin film circuit board device further comprises a conductive adhesive to bond the first and second contact parts together in the through hole.

### BRIEF DESCRIPTION OF THE DRAWINGS

The above and other features and advantages of the present invention will become apparent in the following detailed description of the preferred embodiments with reference to the accompanying drawing, of which:

FIG. 1 is an exploded perspective view illustrating the general structure of a thin film circuit board device of this invention;

FIG. 2 is a fragmentary schematic sectional view of the first preferred embodiment of this invention;

FIG. 3 is a fragmentary schematic sectional view of the second preferred embodiment of this invention;

FIG. 4 is a fragmentary schematic sectional view of the third preferred embodiment of this invention; and

FIG. 5 is a fragmentary schematic sectional view of the fourth preferred embodiment of this invention.

### DETAILED DESCRIPTION OF THE PREFERRED EMBODIMENTS

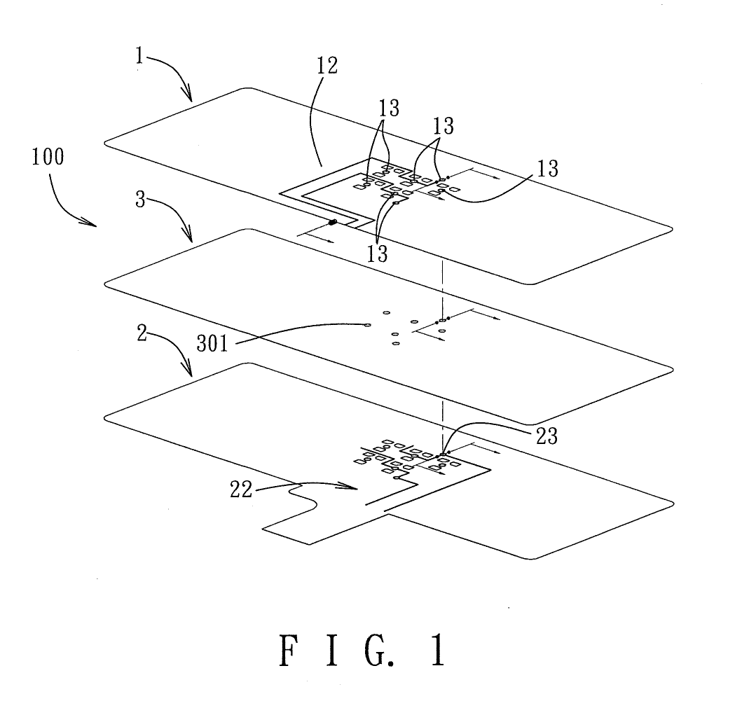

FIG. 1 shows the general structure of a thin film circuit board device 100 of the present invention. The thin film circuit board device 100 comprises an upper circuit layer 1, a lower circuit layer 2, and an insulating layer 3.

As shown in FIG. 1, the upper circuit layer 1 is formed with an upper circuit 12 having at least one first contact part 13. In the embodiments of this invention, the upper circuit 12 has seven first contact parts 13.

The lower circuit layer 2 is disposed below the upper circuit layer 1 and is formed with a lower circuit 22 having at least one second contact part 23 disposed beneath the first contact part 13. The number of the second contact part 23 is equal to that of the first contact part 13. Thus, in the embodiments of this invention, seven second contact parts 23 are formed on the lower circuit 22.

The insulating layer 3 is disposed between the upper and lower circuit layers 1, 2 and has at least one through hole 301 corresponding to the first and second contact parts 13, 23. In the embodiments of this invention, the insulating layer 3 has seven through holes 301 (see FIG. 1). For the sake of brevity, the connection relationship between one set of the first and second contacts parts 13, 23 respectively disposed on the upper and lower circuit layers 1, 2 is shown in the following figures.

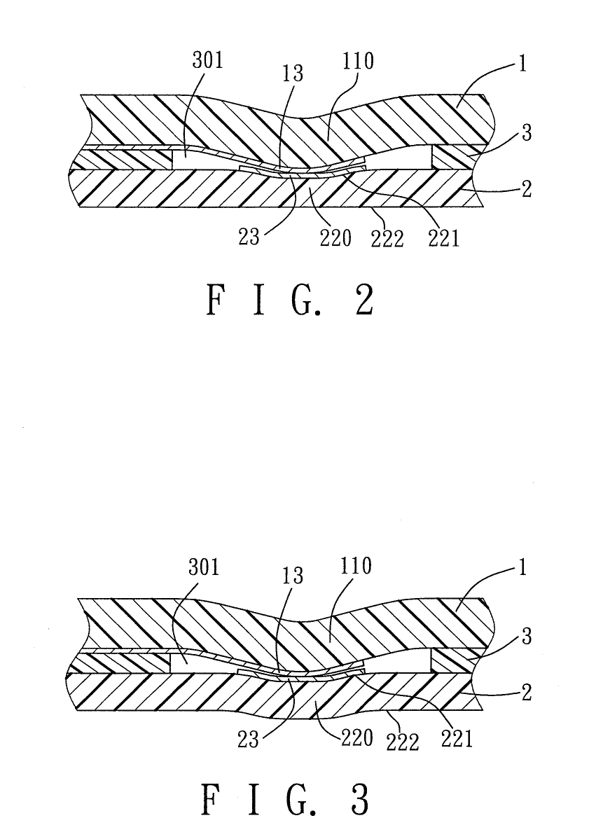

FIG. 2 illustrates the first preferred embodiment of the multi-layered circuit unit of the thin film circuit board device 100 of this invention. In this embodiment, the upper circuit layer 1 has seven preformed protruding portions 110, each having one of the first contact parts 13 formed thereon. The lower circuit layer 2 includes seven pressed portions 220, each having one of the second contact parts 23 formed thereon. As shown in FIG. 2, the preformed protruding portion 110 on the upper circuit layer 1 protrudes into the respective through hole 301 toward the lower circuit layer 2 so that the first contact part 13 disposed on the preformed protruding portion 110 is in constant contact with the second contact part 23 formed on the corresponding pressed portion 220 of the lower circuit layer 21. In this embodiment, each of the pressed portions 220 has a concave face 221 on which the respective second contact part 23 is formed, and a planar face 222 opposite to the concave face 221.

FIG. 3 illustrates the second preferred embodiment of this invention. The structure of the thin film circuit board device 100 in this embodiment is generally similar to that of the first preferred embodiment. The difference between the first and second preferred embodiments resides in that each of the pressed portions 220 has a concave face 221 on which the respective second contact part 23 is formed, and a convex face 222 opposite to the concave face 221.

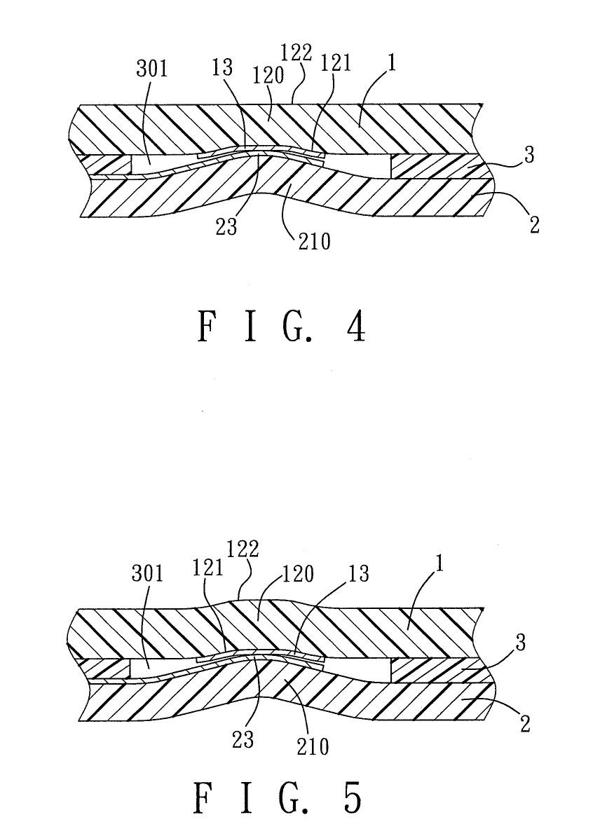

Referring to FIG. 4, in the third preferred embodiment of this invention, the lower circuit layer 2 has seven preformed protruding portions 210 and the upper circuit layer 1 has the pressed portions 120. The second contact parts 23 formed on the preformed protruding portions 210 extend into the through holes 301 and contact the first contact parts 13 formed on the pressed portions 120. In this embodiment, each of the pressed portions 120 has a concave face 121 on which the respective first contact part 13 is formed, and a planar face 122 opposite to the concave face 121.

Referring to FIG. 5, in the fourth preferred embodiment of this invention, the structure of the thin film circuit board device 100 in this embodiment is generally similar to that of the third preferred embodiment. The difference between the third and fourth preferred embodiments resides in that each of the pressed portions 120 has a concave face 121 on which the respective first contact part 13 is formed, and a convex face 122 opposite to the concave face 121.

In the embodiments of this invention, the thin film circuit board device 100 may further include a conductive adhesive (not shown) to bond the first and second contact parts 13, 23 together in the through holes 301 for enhancing structural and electrical connection therebetween.

It should be noted that, if the preformed protruding portions 110, 210 are made from a material having elasticity, elasticity of the material should be destroyed during formation of the preformed protruding portions 110, 210 to prevent the preformed protruding portions 110, 210 from deformation.

By virtue of the preformed protruding portions 110, 210 that protrude into the through holes 301 toward the pressed portions 120, 220, the first and second contact parts 13, 23 can be kept in constant contact with each other. Thus, the electrical connection between the first and second contact parts 13, 23 can be achieved without using the conductive adhesive.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A thin film circuit board device, comprising:
a multi-layered circuit unit that includes:
an upper circuit layer formed with an upper circuit having at least one first contact part;
a lower circuit layer disposed below said upper circuit layer and formed with a lower circuit having at least one second contact part disposed beneath said first contact part; and
an insulating layer disposed between said upper and lower circuit layers and having at least one through hole corresponding to said first and second contact parts;
wherein one of said upper and lower circuit layers has at least one preformed protruding portion that protrudes into said through hole toward the other one of said upper and lower circuit layers, one of said first and second contact parts being disposed on said preformed protruding portion so as to be in constant contact with the other one of said first and second contact parts.

2. The thin film circuit board device of claim 1, wherein said upper circuit layer has said preformed protruding portion, and said first contact part is formed on said preformed protruding portion, extends into said through hole and contacts said second contact part.

3. The thin film circuit board device of claim 2, wherein said lower circuit layer has a pressed portion having a concave face on which said second contact part is formed, and a convex face opposite to said concave face.

4. The thin film circuit board device of claim 1, wherein said lower circuit layer has said preformed protruding portion, and said second contact part is formed on said preformed protruding portion, extends into said through hole and contacts said first contact part.

5. The thin film circuit board device of claim 4, wherein said upper circuit layer has a pressed portion having a concave face on which said first contact part is formed, and a convex face opposite to said concave face.

6. The thin film circuit board device of claim 1, further comprising a conductive adhesive to bond said first and second contact parts together in said through hole.
